(19) United States
(12) Patent Application Publication
(10) Pub. No.: US 2024/0155785 A1
(43) Pub. Date: May 9, 2024

(54) PROFILED DISPLAY PANEL AND DISPLAY DEVICE

(71) Applicant: Xiamen Tianma Micro-Electronics Co., Ltd., Xiamen (CN)

(72) Inventors: Ling WU, Xiamen (CN); Chuhui FENG, Xiamen (CN); Poping SHEN, Xiamen (CN)

(21) Appl. No.: 18/122,249

(22) Filed: Mar. 16, 2023

(30) Foreign Application Priority Data
Nov. 3, 2022 (CN) 202211369113.X

(51) Int. Cl. H05K 5/02

(52) U.S. Cl. CPC H05K 5/0217

(57) ABSTRACT

A profiled display panel including a profiled edge, a regular display area, a profiled display area, and a plurality of pixel units, the profiled display area at least partially surrounding the regular display area, the profiled display area including the profiled edge; each pixel unit including a first pixel unit and a second pixel unit, the first pixel unit being located in the profiled display area, the second pixel unit being located in the regular display area, where an orthographic projection area of the first pixel unit on a light-emitting surface of the profiled display panel is S1, and an orthographic projection area of the second pixel unit on the light-emitting surface of the profiled display panel is S2, S1≤S2.

### CROSS-REFERENCE TO RELATED APPLICATIONS

The present application claims the priority of Chinese Patent Application No. 202211369113.X, filed on Nov. 3, 2022, the content of which is incorporated herein by reference in its entirety.

### TECHNICAL FIELD

The present disclosure relates to the field of display technology and, more specifically, to a profiled display panel and a display device.

### BACKGROUND

In existing technology, there are more and more profiled display products, and there are more and more low-pixels per inch (PPI) products, such as various vehicle-mounted displays and outdoor displays, on the market adopting the profiled designs. The shapes of these display products vary greatly. Due to the large pixel unit of low-PPI products, there are obvious edge jagged phenomena in use, and the transition is not smooth enough. Therefore, there is a need to provide a panel that can improve the edge jagging in low-PPI profiled display products.

### SUMMARY

One aspect of the present disclosure provides a profiled display panel. The profiled display panel includes a profiled edge, a regular display area, a profiled display area, and a plurality of pixel units. The profiled display area at least partially surrounds the regular display area, and the profiled display area includes the profiled edge. Each pixel unit includes a first pixel unit and a second pixel unit. The first pixel unit is located in the profiled display area, and the second pixel unit is located in the regular display area. An orthographic projection area of the first pixel unit on a light-emitting surface of the profiled display panel is S1, and an orthographic projection area of the second pixel unit on the light-emitting surface of the profiled display panel is S2, S1≤S2. Along a first direction and/or a second direction, a distance between center points of at least part of two adjacently arranged first pixel units is R1, and along the first direction and/or the second direction, a distance between center points of tow adjacently arranged second pixel units is R2, R1<R2. The first direction intersects the second direction.

Another aspect of the present disclosure provides a display device. The display device includes a profiled display panel. The profiled display panel includes a profiled edge, a regular display area, a profiled display area, and a plurality of pixel units. The profiled display area at least partially surrounds the regular display area, and the profiled display area includes the profiled edge. Each pixel unit includes a first pixel unit and a second pixel unit. The first pixel unit is located in the profiled display area, and the second pixel unit is located in the regular display area. An orthographic projection area of the first pixel unit on a light-emitting surface of the profiled display panel is S1, and an orthographic projection area of the second pixel unit on the light-emitting surface of the profiled display panel is S2, S1≤S2. Along a first direction and/or a second direction, a distance between center points of at least part of two adjacently arranged first pixel units is R1, and along the first direction and/or the second direction, a distance between center points of tow adjacently arranged second pixel units is R2, R1<R2. The first direction intersects the second direction.

Consistent with the present disclosure, the profiled display panel and the display device provided by the embodiments of the present disclosure at least achieve the following beneficial effects. In the profiled display panel and the display device provided by the embodiments of the present disclosure, by setting the orthographic projection area of the first pixel unit 141 located in the profiled display area to be smaller than or equal to the orthographic projection area of the second pixel unit located in the regular display area 13, and in the first direction and/or the second direction, by setting the distance between the center points of at least part of the adjacently arranged two first pixel units to be smaller than the distance between the center points of two adjacently arranged second pixel units, the pixel density of the edge pixel area (e.g., the profiled display area) can be increased, such that the jaggedness of pixels in the profiled edge area can be weakened, thereby making the edge display of the profiled display panel more smooth.

Of course, any product implementing the technical solutions of the present disclosure does not need to achieve all of the technical effects described above at the same time.

Other features of the present disclosure and advantages thereof will become apparent from the following detailed description of exemplary embodiments of the present disclosure with reference to the accompanying drawings.

### BRIEF DESCRIPTION OF THE DRAWINGS

In order to illustrate the technical solutions in accordance with the embodiments of the present disclosure more clearly, the accompanying drawings to be used for describing the embodiments are introduced briefly in the following. It is apparent that the accompanying drawings in the following description are only some embodiments of the present disclosure. Persons of ordinary skill in the art can obtain other accompanying drawings in accordance with the accompanying drawings without any creative efforts.

FIG. 1 is a schematic diagram of a profiled display panel according to an embodiment of the present disclosure.

FIG. 2 is a schematic diagram of an area A in FIG. 1.

FIG. 3 is a schematic diagram of the area A in FIG. 1 according to an embodiment of the present disclosure.

FIG. 4 is another schematic diagram of the area A in FIG. 1 according to an embodiment of the present disclosure.

FIG. 5 is a schematic diagram of an area B in FIG. 4 according to an embodiment of the present disclosure.

FIG. 6 is another schematic diagram of the area A in FIG. 1 according to an embodiment of the present disclosure.

FIG. 7 is another schematic diagram of the area A in FIG. 1 according to an embodiment of the present disclosure.

FIG. 8 is another schematic diagram of the area A in FIG. 1 according to an embodiment of the present disclosure.

FIG. 9 is another schematic diagram of the area A in FIG. 1 according to an embodiment of the present disclosure.

FIG. 10 is another schematic diagram of the area A in FIG. 1 according to an embodiment of the present disclosure.

FIG. 11 is another schematic diagram of the area A in FIG. 1 according to an embodiment of the present disclosure.

FIG. 12 is a schematic diagram of a first pixel unit and a second pixel unit according to an embodiment of the present disclosure.

FIG. 13 is another schematic diagram of the first pixel unit and the second pixel unit according to an embodiment of the present disclosure.

FIG. 14 is another schematic diagram of the area A in FIG. 1 according to an embodiment of the present disclosure.

FIG. 15 is a schematic diagram of an area C in FIG. 14 according to an embodiment of the present disclosure.

FIG. 16 is another schematic diagram of the area C in FIG. 14 according to an embodiment of the present disclosure.

FIG. 17 is a schematic diagram of an area D in FIG. 9 according to an embodiment of the present disclosure.

FIG. 18 is an enlarged view of an area E in FIG. 17 according to an embodiment of the present disclosure.

FIG. 19 is an enlarged view of an area F in FIG. 17 according to an embodiment of the present disclosure.

FIG. 20 is another schematic diagram of the area D in FIG. 9 according to an embodiment of the present disclosure.

FIG. 21 is schematic diagram of a display device according to an embodiment of the present disclosure.

### DETAILED DESCRIPTION OF THE EMBODIMENTS

Various exemplary embodiments of the present disclosure are described in detail with reference to the drawings. It should be noted that relative arrangement of components and steps, numerical expressions and values clarified in the embodiments are not intended to limit the scope of the present disclosure, unless otherwise specified.

The following description of the at least one exemplary embodiment is merely illustrative and shall not be constructed as any limitation on the present disclosure and its application or use.

Techniques, methods and apparatus known to those skilled in the art may not be discussed in detail, but the techniques, methods and apparatus should be considered as a part of the specification where appropriate.

In all of the examples shown and discussed herein, any specific values are to be construed as illustrative only rather than limitation. Thus, different values may be used in other examples of the exemplary embodiments.

It should be noted that similar reference numerals and letters indicate similar items in the following drawings. Therefore, once an item is defined in one drawing, the item is unnecessary to be further discussed in subsequent drawings.

In existing technology, there are more and more profiled display products, and there are more and more low-pixels per inch (PPI) products, such as various vehicle-mounted displays and outdoor displays, on the market adopting the profiled designs. The shapes of these display products vary greatly. Due to the large size of the pixel unit of low-PPI products, even if some transitions are adopted for the profiled edge, such as setting the light-emitting area or the light-transmitting area of the profiled edge to be relatively small, for low-PPI display products, there are still obvious edge-jagged phenomena in use, and the transition is not smooth enough. Therefore, there is a need to provide a panel that can improve the edge jagged display of low-PPI profiled display products.

In view of the foregoing, embodiments of the present disclosure provide a profiled (e.g., irregularly-shaped or specially-shaped) display panel and a display device that can be used to improve the edge-jagged display of profiled display products.

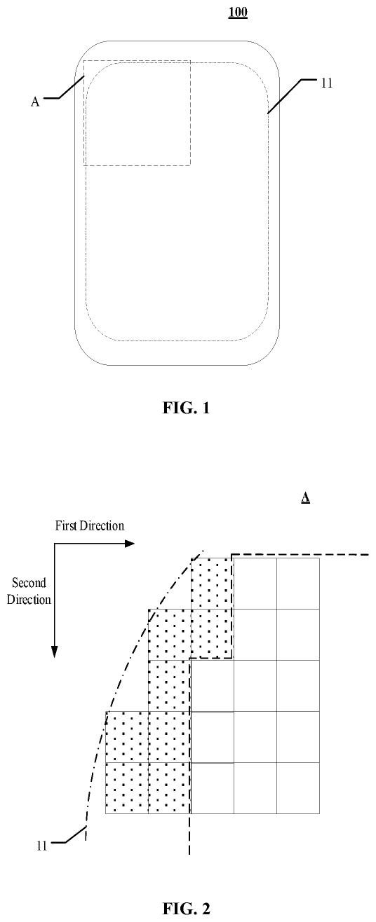

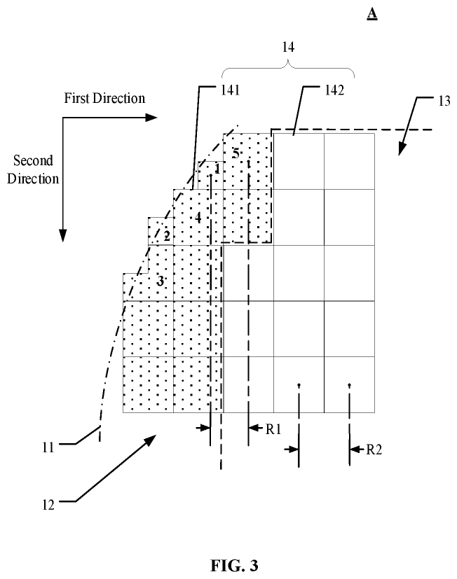

FIG. 1 is a schematic diagram of a profiled display panel, FIG. 2 is a schematic diagram of an area A in FIG. 1, and FIG. 3 is a schematic diagram of the area A in FIG. 1 according to an embodiment of the present disclosure. Referring to FIG. 1 to FIG. 3, an embodiment of the present disclosure provides a profiled display panel 100, and the profiled display panel 100 includes a profiled edge 11. The profiled display panel 100 includes a profiled display area 12 and a regular display area 13, and the profiled display area 12 at least partially surrounds the regular display area 13. The profiled display area 12 includes the profiled edge 11. The profiled display panel 100 includes a plurality of pixel units 14. The pixel unit 14 includes a first pixel unit 141 and a second pixel unit 142. The first pixel unit 141 may be located in the profiled display area 12, and the second pixel unit 142 may be located in the regular display area 13. The orthographic projection area of the first pixel unit 141 on the light-emitting surface of the profiled display panel 100 may be S1, and the orthographic projection area of the second pixel unit 142 on the light-emitting surface of the profiled display panel 100 may be S2, and S1 S2. Along a first direction and/or a second direction, a distance between the center points of at least part of the adjacently arranged two first pixel units 141 may be R1, along the first direction and/or the second direction, a distance between the center points of the adjacently arranged two second pixel units 142 may be R2, and R1<R2. In some embodiments, the first direction and the second direction may intersect.

More specifically, the embodiments of the present disclosure provide a display panel. The display panel includes a profiled edge 11 to form a profiled display panel 100. In the display area (12 and 13) of the profiled display panel 100, the part close to the profiled edge 11 may be the profiled display area 12, and the part of the display area of the profiled display area 12 away from the profiled edge 11 may be the regular display area 13. That is, the profiled display area 12 may be at least partially arranged to surround the regular display area 13.

The profiled display panel 100 provided in the present disclosure may include a plurality of pixel units 14. Since the profiled display panel 100 includes the profiled display area 12 and the regular display area 13, in the present disclosure, the plurality of pixel units 14 arranged in the profiled display area 12 may be classified as the first pixel units 141 and the pixel units 14 arranged in the regular display area 13 may be classified as second pixel units 142. In FIG. 3, for the first pixel unit 141 marked as “1” shown in the first row and the second column, or the first pixel unit 141 marked as “2” shown in the first column and the second row, or the first pixel unit 141 marked as “3” shown in the first column and the third row, the area of these first pixel units 141 may be selected to be smaller than the area of the second pixel units 142. Alternatively, in FIG. 3, for the first pixel unit 141 marked as “4” shown in the second row and the second column, the area of this first pixel unit 141 may be selected to be equal to the area of the second pixel units 142. The area of the first pixel unit 141 may be the orthographic projection area S1 of the first pixel unit 141 on the light-emitting surface of the profiled display panel 100, and the area of the second pixel unit 142 may be the orthographic projection area S2 of the second pixel unit 142 on the light-emitting surface of the profiled display panel 100. In addition, the area of the pixel unit 14 (the first pixel unit 141 and the second pixel unit 142) may include not only the area of its light-transmitting area, but also the area occupied by the driving circuit of each pixel unit 14. Based on this, the present disclosure may choose to further define that along the first direction, there may be at least a distance R1 between the center points of two adjacent first pixel units 141, such as the distance R1 between the center points of two adjacently arranged first pixel unit 141 marked as “1” as shown in the first row and the first column in FIG. 3 and the first pixel unit 141 marked as “5” as shown in the first row and the second column in FIG. 3, less than the distance R2 between the center points of two adjacent second pixel units 142; and/or, along the second direction, at least the distance R1 between the center points of two adjacently arranged first pixel units 141 may be smaller than the distance R2 between the center points of two adjacently arranged second pixel units 142. For example, the distance R1 between the center points between the first pixel units 141 marked as “1” and “4” arranged adjacent to each other along the second direction in the FIG. 3 is smaller than R2. The unfilled pixel units 14 shown in FIG. 3 represent the second pixel units 142. In this way, there are pixel units 14 in the profiled display area 12 that are smaller in size than those in the regular display area 13. Therefore, compared with the conventional regular display area 13, the PPI of the pixel units 14 in the profiled display area 12 can be improved to a certain extent. That is, by increasing the number of pixel units 14 per unit area, the pixel units 14 close to the profiled edge 11 can include smaller pixel units 14, thereby making the transition of the profiled edge 11 more gentle, which prevents the user from being able to easily identify the jagged edges with human eyes, thereby improving the display effect of the profiled display panel 100.

It should be noted that as shown in FIG. 3 of the present disclosure, the first pixel units 141 marked as “1”, “2”, and “3” have an area S1 much smaller than an area S2 of the second pixel units 142. In the conventional technical solution provided in FIG. 2, the area of each pixel unit in the profiled display area and the area of each pixel unit in the regular display area are set to be the same. That is, if the PPI of the pixel units in the profiled display area and the regular display area are the same, the profiled display area will not have the first pixel units 141 marked as “1”, “2”, and “3” in FIG. 3 with the relatively smaller area. Therefore, compared with the conventional technology, the technical solution provided by the present disclosure can increase the number of first pixel units 141 in the same area in the profiled display area 12 to a certain extent. In this way, the PPI of the pixel units 14 in the profiled display area 12 can be increased, such that the transition of the profiled edge 11 is smoother, and the display effect of the profiled display panel 100 is improved.

It should be noted that the present disclosure does not limit the specific shape of the profiled display panel 100. For example, the profiled display panel may be embodied as including curved corners (as shown in FIG. 1 and FIG. 3), folded corners, etc., and the user may choose the specific shape of the profiled display panel 100 based on actual needs.

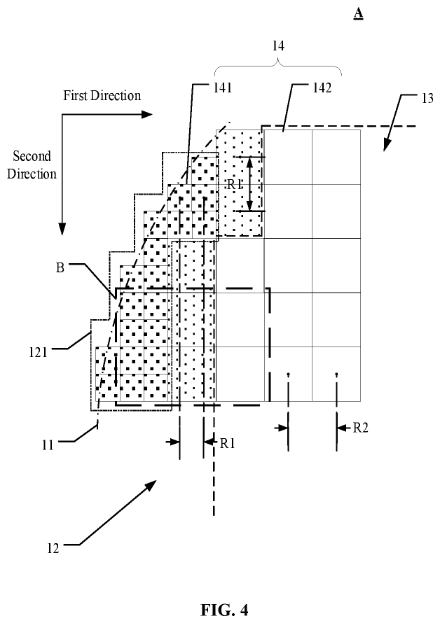

FIG. 4 is another schematic diagram of the area A in FIG. 1 according to an embodiment of the present disclosure. Referring to FIG. 1 and FIG. 4. In some embodiments, the profiled display area 12 may include a first area 121, in the first area 121 S1<S2, and R1<R2.

In some embodiments, the profiled display area 12 may include the first area 121. The first area 121 may be the side area relatively far away from the regular display area 13 in the profiled display area 12, that is, the first area 121 may be the part of the profiled display area 12 that does not connect with the regular display area 13 int eh profiled display area 12 as much as possible. The area S1 of the first pixel unit 141 in the first area 121 may be set to be smaller than the area S2 of the second pixel unit 142. Based on this, at the same time, along the first direction, at least the distance R1 between the center points of two adjacently arranged first pixel units 141 may be set to be smaller than the distance R2 between the center points of two adjacently arranged second pixel units 142; and/or, along the second direction, at least the distance R1 between the center points of two adjacently arranged first pixel units 141 may be set to be smaller than the distance R2 between the center points of two adjacently arranged second pixel units 142. In this way, in the first area 121 close to the profiled edge 11 of the profiled display area 12, the number of pixel units 14 in the same area can be more than the number of pixel units 14 in the same area in FIG. 2. That is, the PPI of the pixel units 14 in the first area 121 can be higher than the PPI of the pixel units 14 in the regular display area 13. That is, by increasing the number of pixel units 14 per unit area in the first area 121, the transition of the profiled edge 11 can be smoother, which prevents the user from being able to easily recognize the edge jagged phenomenon by human eyes, thereby improving the display effect of the profiled display panel 100.

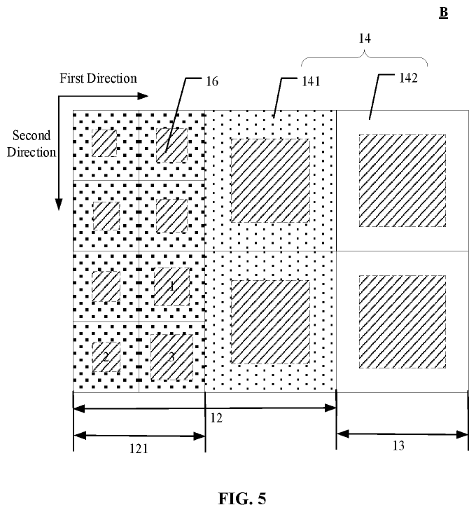

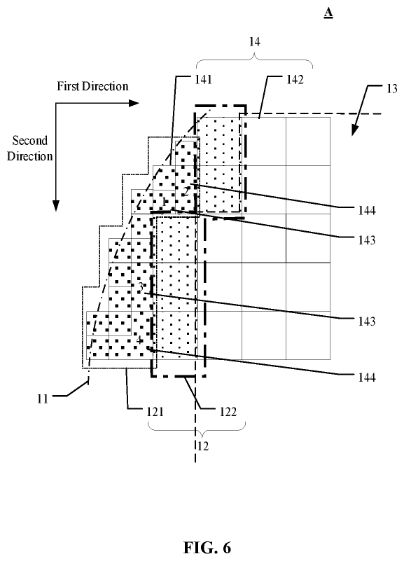

FIG. 5 is a schematic diagram of an area B in FIG. 4 according to an embodiment of the present disclosure. Referring to FIG. 1, FIG. 4, and FIG. 5. In some embodiments, in the first area 121, along the first direction and/or the second direction, the orthographic projection areas of at least two adjacent first pixel units 141 on the light-emitting surface of the profiled display panel 100 may be the same; and along the first direction and/or the second direction, a light transmission area 16 of the first pixel unit 141 close to the profiled edge 11 may be smaller than the light transmission area 16 of the first pixel unit 141 away from the profiled edge 11.

In some embodiments, in the first area 121 of the profiled display area 12, along the first direction, the areas of the adjacent two first pixel units 141 may be the same, and/or along the second direction, the areas of the two adjacent first pixel units 141 may be the same. At the same time, along the first direction, the light transmission area 16 of the first pixel unit 141 close to the profiled edge 11 in the profiled display area 12 may be set to be smaller than the /15 of the first pixel unit 141 on the side close to the regular display area 13, and/or, along the second direction, the light transmission area 16 of the first pixel unit 141 close to the profiled edge 11 of the profiled display area 12 may be set to be smaller than the light transmission area 16 of the first pixel unit 141 on the side close to the regular display area 13. In this way, the area of the peripheral first pixel units 141 close to the side of the profiled edge 11 in the profiled display area 12 may be set to be equal, and all the first pixel units 141 located in the first area 121 may be made into equal with the same shape and size, such that the division of the pixel units 14 in the area is simpler. In addition, it is more convenient to carry out regularization and modularization in the production process of this part of the pixel unit 14, and the wiring related to this part of the pixel unit 14 is also relatively simple, avoiding the need for excessive crossing and winding. At the same time, the light transmission area 16 of the peripheral first pixel units 141 close to the side of the profiled edge 11 in the profiled display area 12 can be set to be relatively smaller than the light transmission area 16 of other areas, such that the display brightness of the first pixel units 141 in the area close to the profiled edge 11 of the profiled display area 12 can be lower. In this way, the user is less likely to recognize the jagged edge of the profiled display panel 100, making the display of the profiled edge 11 of the profiled display panel 100 smoother, thereby improving the display effect of the profiled display panel 100 and improving user experience.

FIG. 6 is another schematic diagram of the area A in FIG. 1 according to an embodiment of the present disclosure. Referring to FIG. 1, FIG. 4, and FIG. 6. In some embodiments, in the first area 121, along the first direction and/or the second direction, at least two adjacent first pixel units 141 may have different orthographic projection areas on the light-emitting surface of the profiled display panel 100.

In some embodiments, in the first area 121 of the profiled display area 12, the areas of two adjacently arranged first pixel units 141 along the first direction may be set to be different (such as the first pixel units 141 marked as “1” and “2” in FIG. 6), and/or, the areas of the two adjacently arranged first pixel units 141 along the second direction may be set to be different (such as the first pixel units 141 marked as “3” and “4” in FIG. 6). That is, as shown in FIG. 4, the peripheral first pixel units 141 close to the side of the profiled edge 11 in the profiled display area 12 can be selected to have the same orthographic projection area, and as shown in FIG. 6, the orthographic projections of some of the first pixel units 141 can be set to be different. In addition, the orthographic projections of all the first pixel units 141 may be set to be different, which is not limited in the embodiments of the present disclosure. The user may adjust the orthographic projection area of the first pixel units 141 on the light-emitting surface of the profiled display panel 100 in the profiled display area 12 close to the side of the profiled edge 11 based on actual needs as long as the orthographic projection area of the first pixel units 141 can be adapted to the corresponding profiled edge 11 to weaken the jagged effect of the profiled edge 11.

Referring to FIG. 1, FIG. 4, and FIG. 6. In some embodiments, in the first area 121, the first pixel unit 141 may include a first pixel unit A 143 and a first pixel unit B 144. The orthographic projection area of the first pixel unit A 143 on the light-emitting surface of the profiled display panel 100 may be S11, and the orthographic projection area of the first pixel unit B 144 on the light-emitting surface of the profiled display panel 100 may be S12, S11<S12. Along the first direction, the first pixel unit B 144 may be located on the side of the first pixel unit A 143 facing the regular display area 13; and/or, along the second direction, the first pixel unit B 144 may be located on the side of the first pixel unit A 143 facing the regular display area 13.

In some embodiments, in the first area 121 close to the profiled edge 11 of the profiled display area 12, there may be a plurality of first pixel units 141. In order to clearly illustrate the embodiments provided in the present disclosure, based on the different orthographic projection areas of the first pixel units 141 on the light-emitting surface of the profiled display panel 100, the first pixel unit 141 in the first area 121 may be divided into the first pixel unit A 143 and the first pixel unit B 144. In some embodiments, the orthographic projection area S11 of the first pixel unit A 143 may be smaller than the orthographic projection area S12 of the first pixel unit B 144. At this time, along the first direction, the first pixel unit B 144 may be set to be located on the side of the first pixel unit A 143 facing the regular display area 13. For example, the first pixel unit 141 marked as “2” is located on the side of the first pixel unit 141 marked as “1” facing the regular display area 13 in FIG. 6. In addition, along the second direction, the first pixel unit B 144 may be set to be located on the side of the first pixel unit A 143 facing the regular display area 13. For example, the first pixel unit 141 marked as “4” is located on the side of the first pixel unit 141 marked as “3” facing the regular display area 13 in FIG. 6. That is, in the first area 121, the first pixel unit B 144 with a relatively large orthographic projection area, compared with the first pixel unit A 143 with a relatively small orthographic projection area, can be set to be closer to the regular display area 13. That is, the first pixel unit A 143 with a relatively small orthographic projection area can be arranged next to the profiled edge 11, while the first pixel unit B 144 with the relatively large orthographic projection area can be arranged on the side of the first pixel unit A 143 away from the profiled edge 11. In this way, in the profiled display area 12, the PPI of the pixel units 14 closer to the profiled edge 11 can be made higher, thereby increasing the number of pixel units 14 arranged in a unit area near the profiled edge 11, which achieves the effect of smoother transition of the profiled edge 11, avoids the user from being able to easily recognize the edge jagged phenomenon, thereby improving the display effect of the profiled display panel 100. In addition, as shown in FIG. 6, the pixel units 14 on the side close to the profiled edge 11 can have different shapes and different areas, and the pixel units 14 can be set to be irregularly divided, such that the pixel units 14 can be differentiated based on the specific curvature of the profiled edge 11. In this way, the pixel units 14 close to the profiled edge 11 can be more closely attached to the profiled edge 11, such that the display of the edge of the profiled display panel 100 can be smoother, and the display effect is more delicate.

Referring to FIG. 1 to FIG. 4 and FIG. 6. In some embodiments, the profiled display area 12 may further includes a second area 122. Along the direction from the profiled display area 12 to the regular display area 13, the second area 122 may be located between the first area 121 and the regular display area 13, and in the second area 122, S1=S2, and R1=R2.

In some embodiments, the profiled display area 12 may be divided into the first area 121 and the second area 122. In FIG. 4, the part other than the first area 121 in the profiled display area 12 belongs to the second area 122. In some embodiments, along the direction of the profiled display area 12 towards the regular display area 13, the second area 122 may be located between the first area 121 and the regular display area 13, that is, the second area 122 may be closer to the regular display area 13 than the first area 121. That is, the second area 122 here may be equivalent to a transition area between a side area (e.g., the first area 121) close to the profiled edge 11 and the regular display area 13. Based on this, in some embodiments, in the second area 122, the area of the first pixel unit 141 may be set to be equal to the area of the second pixel unit 142. The area of the first pixel unit 141 may be the orthographic projection area S1 of the first pixel unit 141 on the light-emitting surface of the profiled display panel 100, and the area of the second pixel unit 142 may be the orthographic projection area S2 of the second pixel unit 142 on the light-emitting surface of the profiled display panel 100. In addition, the area of the pixel unit 14 (the first pixel unit 141 and the second pixel unit 142) may include not only the area of its light-transmitting area, but also the area occupied by the driving circuit of each pixel unit 14. At the same time, in the second area 122, along the first direction, at least the distance R1 between the center points of two adjacently arranged first pixel units 141 may be set to equal to the distance R2 between the center points of two adjacently arranged second pixel units 142; and/or, along the second direction, at least the distance R1 between the center points of two adjacently arranged first pixel units 141 may be set to equal to the distance R2 between the center points of two adjacently arranged second pixel units 142.

That is, since the second area 122 is the area next to the regular display area 13 in the profiled display area 12, the second area 122 of the profiled display area 12 may be arranged to include pixel units 14 having the same area as the pixel units 14 of the regular display area 13, and the second area 122 may be further arranged to include pixel units 14 whose center distance between two adjacent pixel units 14 is the same as the center distance between two adjacent pixel units 14 in the regular display area 13. In this way, some pixel units 14 in the second area 122 can be the same as the pixel units 14 of the regular display area 13, and there is an opportunity to set the display effect of at least part of the pixel units 14 in the second area 122 to be the same as the display effect of the regular display area 13, thereby avoiding visible display difference to the human eyes between the pixel units 14 in the second area 122 in the profiled display area 12 and the pixel units 14 in the regular display area 13 by weakening or eliminating the display difference between the regular display area 13 and the profiled display area 12 in the profiled display panel 100 due to the different arrangement of the pixel units 14. In this way, the display boundary between the regular display area 13 and the profiled display area 12 can be weakened or eliminated to improve the overall display uniformity of the profiled display panel 100 and to enhance the user experience.

Referring to FIG. 1 to FIG. 6. In some embodiments, in the second area 122, the light transmission area 16 of the first pixel unit 141 may be smaller than the light transmission area 16 of the second pixel unit 142.

More specifically, when at least part of the pixel units 14 in the second area 122 in the profiled display area 12 are set to S1=S2 and R1=R2, in some embodiments, as shown in FIG. 5, the light transmission area 16 of at least part of the first pixel unit 141 in the second area 122 can be set to be smaller than the light transmission area 16 of the second pixel unit 142. In this way, the light transmission area 16 of the first pixel unit 141 in the profiled display area 12 far away from the profiled edge 11 and close to the regular display area 13 side can be smaller than the light transmission area 16 of the second pixel unit 142 of the regular display area 13. At this time, the luminous brightness of the pixel units 14 in the second area 122 will be smaller than the luminous brightness of the pixel units 14 in the regular display area 13, causing the difference between the luminous brightness of the first pixel unit 141 in the second area 122 and the luminous brightness of the first pixel unit 141 in the first area 121 to be relatively small, and at the same time, causing the difference between the luminous brightness of the first pixel unit 141 in the second area 122 and the luminous brightness of the second pixel unit 142 in the regular display area 13 to be relatively small, thereby reducing the display difference between the regular display area 13 and the profiled display area 12, avoiding the difference in display effect between the regular display area 13 and the profiled display area 12 in the profiled display panel 100 by human eyes, and improving the display uniformity of the profiled display panel 100.

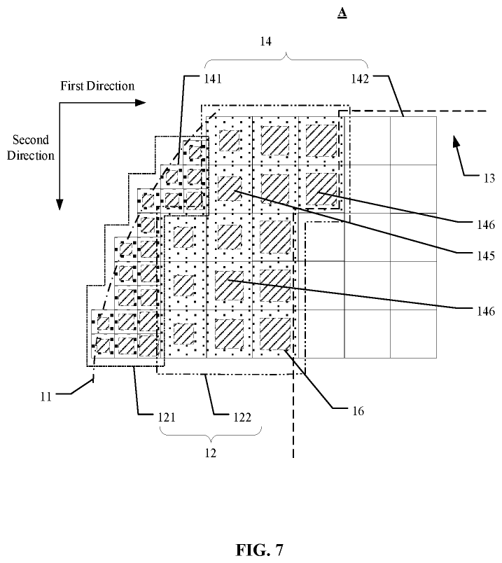

FIG. 7 is another schematic diagram of the area A in FIG. 1 according to an embodiment of the present disclosure. Referring to FIG. 1 and FIG. 7. In some embodiments, in the second area 122, the orthographic projection area of the first pixel units 141 on the light-emitting surface of the profiled display panel 100 may all be the same; in the second area 122, the first pixel unit 141 may include a first pixel unit C 145 and a first pixel unit D 146, the light transmission area 16 of the first pixel unit C 145 being P1 the light transmission area 16 of the first pixel unit D 146 being P2, P1<P2; along the first direction, the first pixel unit D 146 may be located on the side of the first pixel unit C 145 facing the regular display area 13; and/or, along the second direction, the first pixel unit D 146 may be located on the side of the first pixel unit C 145 facing the regular display area 13.

More specifically, in the second area 122, along the first direction, the first pixel unit D 146 with a relatively large light transmission area 16 may be arranged to be on the side of the first pixel unit C 145 with a relatively small light transmission area 16 facing the regular display area 13; and/or, along the second direction, the first pixel unit D 146 with a relatively large light transmission area 16 may be arranged to be on the side of the first pixel unit C 145 with a relatively small light transmission area 16 facing the regular display area 13. That is, in the second area 122, the orthographic projection areas of the first pixel units 141 in the second area 122 on the light-emitting surface of the profiled display panel 100 may all set to be the same. At this time, the light transmission area 16 of the first pixel units 141 in the second area 122 may gradually increase in the direction along the profiled edge 11 pointing to the regular display area 13. Therefore, in the second area 122, along the direction along the profiled edge 11 pointing to the regular display area 13, when the pixel units 14 are receiving the same driving voltage, the luminous brightness can gradually increase, thereby reducing or eliminating the display difference that can be recognized by the human eyes in the profiled display panel 100, and improving the display uniformity of the profiled display panel 100.

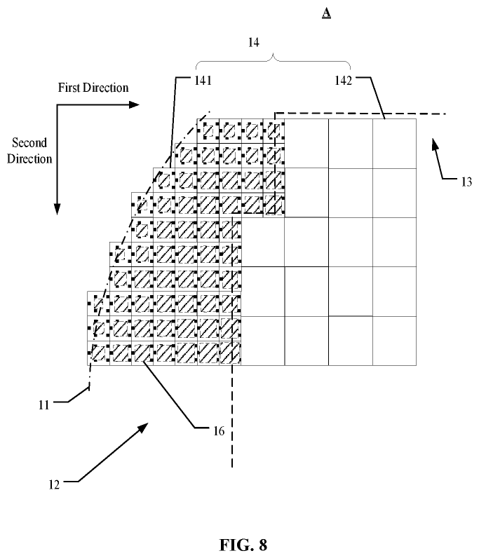

FIG. 8 is another schematic diagram of the area A in FIG. 1 according to an embodiment of the present disclosure. Referring to FIG. 1 and FIG. 8. In some embodiments, in the profiled display area 12, the orthographic projection areas of the first pixel units 141 on the light-emitting surface of the profiled display panel 100 may all be the same, and the distance between the center points of two adjacent first pixel units 141 arranged along the first direction and/or the second direction may be the same; along the first direction and/or the second direction, the light transmission area 16 of the first pixel unit 141 on the side close to the regular display area 13 may be larger than the light transmission area 16 of the first pixel unit 141 on the side away from the regular display area 13.

In some embodiments, all the first pixel units 141 in the profiled display area 12 may be arranged to have the same orthographic projection area on the light-emitting surface of the profiled display panel 100, and the distance between the center points of any adjacent two first pixel units 141 arranged along the first direction and/or the second direction may be set to be the same. At this time, along the first direction and/or the second direction, in the two adjacently arranged first pixel units 141, the light transmission area 16 of the first pixel unit 141 on the side close to the regular display area 13 may be arranged to be larger than the light transmission area 16 of the first pixel unit 141 on the side away from the regular display area 13. That is, in the profiled display area 12, when the orthographic projection areas of the first pixel units 141 on the light-emitting surface of the profiled display panel 100 are all the same, and the distances between the center points of two adjacently arranged first pixel units 141 along the first direction and/or the second direction are the same, in the direction from the profiled edge 11 to the regular display area 13, the light transmission area 16 of the first pixel unit 141 can be arranged to gradually increase. .as in the entire profiled display area 12, along the direction of the profiled edge 11 pointing to the regular display area 13, when the pixel units 14 receive the same driving voltage, the luminous brightness of the pixel units 14 appears to gradually increase. In this way, the brightness difference between the regular display area 13 and the profiled display area 12 can be reduced, and the profiled edge 11 of the profiled display panel 100 can be blurred by relatively low luminous brightness, thereby further improving the smooth transition of the profiled edge 11. In this way, the jagged edges of the profiled display panel 100 that can be easily recognized by human eyes can be avoided, which prevents the user from observing the display difference between the profiled display area 12 and the regular display area 13, thereby improving the display effect of the profiled display panel 100 and improving user experience.

In addition, as shown in FIG. 8, the shape and area of all the pixel units 14 in the entire profiled display area 12 may be arranged to be the same. That is, all the first pixel units 141 located in the profiled display area 12 may be made into an equal structure with the same shape and size, making the division of the pixel units 14 in this area easier. Further, it is also convenient to carry out regular and modular production during the production process of this part of the pixel units 14, and the wiring related to his part of the pixel units 14 is also relatively simple, avoiding the need for differentiating setting such as crossing wires and winding wires. In addition, the first pixel units 141 fabricated by equal division is more convenient to calculate the differential voltage when voltages of different magnitudes need to be applied to the pixel units 14 at different positions.

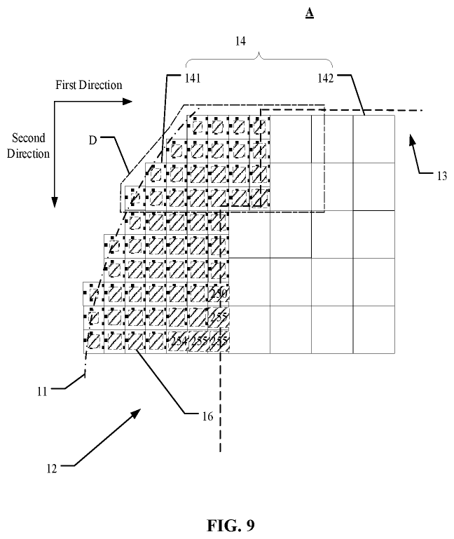

FIG. 9 is another schematic diagram of the area A in FIG. 1 according to an embodiment of the present disclosure. Referring to FIG. 1 and FIG. 9. In some embodiments, along the first direction, the light transmission area 16 of at least two adjacently arranged first pixel unit 141 may be the same; and/or, along the second direction, the light transmission area 16 of at least two adjacently arranged first pixel unit 141 may be the same.

More specifically, when the profiled display area 12 and the regular display area 13 are set to be S1<S2 and R1<R2, in some embodiments, along the first direction and/or the second direction, at least two adjacently arranged first pixel units 141 may have the same light transmission area 16. That is, when the same driving voltage is applied, the display brightness may be the same. For low-PPI products, the profiled edge 11 may be divided into smaller-sized pixel units 14. For smaller-sized pixel units 14, the profiled edge 11 of low-PPI products is relatively long, and at least two adjacent pixel units 14 may have the same light transmission area 16. On one hand, close to the regular display area 13, the difference in the light transmission area 16 can be relatively small. At this time, at least some of the light transmission areas 16 of the pixel units 14 can be set to be consistent, thereby simplifying the edge design of some profiled display panels 100. On the other hand, the transition of the display effect from the profiled edge 11 to the regular display area 13 can be smoother, and the change is not too drastic,

For example, as shown in FIG. 9, in the three pixel units 14 that are adjacent to the regular display area 13 and are arranged in the first direction next to the regular display area 13 in the profiled display area 12, the light transmission areas 16 of the pixel units 14 marked as “255” are the same, and the corresponding display brightness are also the same. The light transmission areas 16 of the pixel units 14 marked as “254” and “250” are relatively small, and the corresponding display brightness are also relatively low, but it is not much different from the display brightness of the pixel units 14 marked as “255”. In addition, the light transmission areas 16 of the pixel units 14 marked as “255” is the same as the light transmission area 16 of each pixel unit 14 in the regular display area 13. That is, along the first direction and/or the second direction, in the three adjacently arranged pixel units 14, the two pixel units 14 adjacent to the regular display area 13 can have the same light transmission area 16. In this way, the boundary between the profiled display area 12 and the regular display area 13 will not be obvious, thereby improving the display effect of the profiled display panel 100.

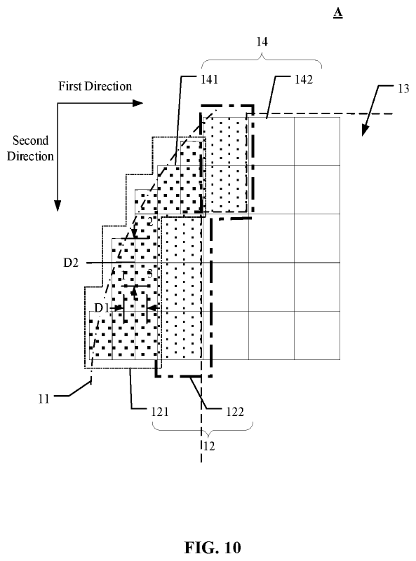

FIG. 10 is another schematic diagram of the area A in FIG. 1 according to an embodiment of the present disclosure. Referring to FIG. 1 and FIG. 10. In some embodiments, in the first area 121, along the first direction, there may be a distance D1 between the center points of at least two adjacently arranged first pixel units 141, and along the second direction, there may be a distance D2 between the center points of at least two adjacently arranged first pixel units 141, D1<D2.

In some embodiments, at least two rectangularly-shaped first pixel units 141 may be arranged in the first area 121 of the profiled display area 12, such as the first pixel units 141 marked as “1”, “2”, and “3” shown in FIG. 10. The distance D1 between the center points of the two first pixel units 141 (the first pixel unit 141 marked as “1” and the first pixel unit 141 marked as “3”) adjacently arranged along the first direction may be set to be smaller than the distance D2 between the center points of the two first pixel units 141 (the first pixel unit 141 marked as “2” and the first pixel unit 141 marked as “3”) adjacently arranged along the second direction. It should be noted that the first pixel units 141 described above are presented as rectangular first pixel units 141 with a wide side along the first direction and a long side along the second direction, but the present disclosure is not limited thereto. In some embodiments, the first area 121 of the profiled display area 12 may also include first pixel units 141 of other shapes.

It should also be noted that the two adjacently arranged rectangularly-shaped first pixel units 141 may be further arranged such that the light transmission areas 16 of the two adjacently arranged first pixel units 141 can gradually increase. In addition, the light transmission areas 16 of the first pixel units 141 may also be arranged based on requirements, as long as the difference between the display brightness of the first pixel units 141 on the side relatively close to the regular display area 13 and the display brightness of the pixel units 14 in the regular display area 13 is relatively small, the display brightness of the first pixel units 141 on the side relatively close to the regular display area 13 and the display brightness of the first pixel units 141 on the side close to the profiled edge 11 have a smooth transition in the regular display area 13, and there is no sudden change in brightness between the regular display area 13 and the profiled display area 12. That is, when setting the first area 121 to include multiple rectangular first pixel units 141, the user may adjust the light transmission area of each first pixel unit 141 in the profiled display area 12 based on requirements, which is not limited in the embodiments of the present disclosure, as long as the transition between the first area 121, the second area 122, and the regular display area 13 is smooth when the profiled display panel 100 is displayed to ensure the display effect of the profiled display panel 100.

In addition, the arrangement of the first pixel units 141 in the first area 121 as shown in FIG. 10 may be applied to the situation where a higher degree of refinement is needed in the first direction than in the second direction. That is, in the embodiments of the present disclosure, small-sized division may be performed only for a certain direction (such as the first direction), and the size of the other direction may remain unchanged.

FIG. 11 is another schematic diagram of the area A in FIG. 1 according to an embodiment of the present disclosure. Referring to FIG. 1 and FIG. 11. In some embodiments, in the first area 121, along the first direction, there may be a distance D1 between the center points of at least two adjacently arranged first pixel units 141, and along the second direction, there may be a distance D2 between the center points of at least two adjacently arranged first pixel units 141, D2<D1.

In some embodiments, at least two rectangularly-shaped first pixel units 141 may be arranged in the first area 121 of the profiled display area 12, such as the first pixel units 141 marked as “1”, “2”, “3”, and “4” shown in FIG. 11. The distance D1 between the center points of the two first pixel units 141 (the first pixel unit 141 marked as “1” and the first pixel unit 141 marked as “2”) adjacently arranged along the first direction may be set to be larger than the distance D2 between the center points of the two first pixel units 141 (the first pixel unit 141 marked as “3” and the first pixel unit 141 marked as “4”) adjacently arranged along the second direction. It should be noted that the first pixel units 141 described above are presented as rectangular first pixel units 141 with a long side along the first direction and a wide side along the second direction, but the present disclosure is not limited thereto. In some embodiments, the first area 121 of the profiled display area 12 may also include first pixel units 141 of other shapes.

It should also be noted that the two adjacently arranged rectangularly-shaped first pixel units 141 may be further arranged such that the light transmission areas 16 of the two adjacently arranged first pixel units 141 can gradually increase. In addition, the light transmission areas 16 of the first pixel units 141 may also be arranged based on requirements, as long as the difference between the display brightness of the first pixel units 141 on the side relatively close to the regular display area 13 and the display brightness of the pixel units 14 in the regular display area 13 is relatively small, the display brightness of the first pixel units 141 on the side relatively close to the regular display area 13 and the display brightness of the first pixel units 141 on the side close to the profiled edge 11 have a smooth transition in the regular display area 13, and there is no sudden change in brightness between the regular display area 13 and the profiled display area 12. That is, when setting the first area 121 to include multiple rectangular first pixel units 141, the user may adjust the light transmission area of each first pixel unit 141 in the profiled display area 12 based on requirements, which is not limited in the embodiments of the present disclosure, as long as the transition between the first area 121, the second area 122, and the regular display area 13 is smooth when the profiled display panel 100 is displayed to ensure the display effect of the profiled display panel 100.

In addition, the arrangement of the first pixel units 141 in the first area 121 as shown in FIG. 11 may be applied to the situation where a higher degree of refinement is needed in the second direction than in the first direction. That is, in the embodiments of the present disclosure, small-sized division may be performed only for a certain direction (such as the second direction), and the size of the other direction may remain unchanged.

It should also be noted that in the embodiment described above, in the first area 121, there are at least two rectangular first pixel units 141 arranged adjacently, which are only two optional arrangements provided in the present disclosure. That is, when the pixel units 14 in the regular display area 13 are in regular rectangular shape (including a square shape), the first pixel units 141 in the profiled display area 12 may be selected to be a rectangular shape (including a square shape), but the present disclosure is not limited thereto. The shape of the first pixel units 141 in the profiled display area 12 may also be adjusted based on requirements, as long as the jagged phenomenon of the profiled edge 11 can be reduced, and the display difference between the regular display area 13 and the profiled display area 12 can be reduced. For example, in the pixel units 14 that are arranged adjacent to the profiled edge 11, it is also possible to completely overlap the side that is connected to the profiled edge 11 and the profiled edge 11. In addition, if the pixel units 14 in the regular display area 13 are in the shape of pentagon, triangle, or other shapes, the shape of the first pixel units 141 in the profiled display area 12 may be adjusted accordingly based on its rules.

It should also be noted that in the embodiments shown in FIG. 10 and FIG. 11, only the first area 121 of the profiled display area 12 includes several rectangular first pixel units 141, but it is also possible to set the pixel units 14 included in the entire profiled display area 12 to be rectangularly shaped first pixel units 141 as shown in FIG. 10, or the pixel units 14 included in the entire profiled display area 12 may all be set to be rectangular first pixel units 141 as shown in FIG. 11. In FIG. 10 and FIG. 11, the extending direction of the long side and the wide side of the rectangular first pixel units 141 are opposite to each other.

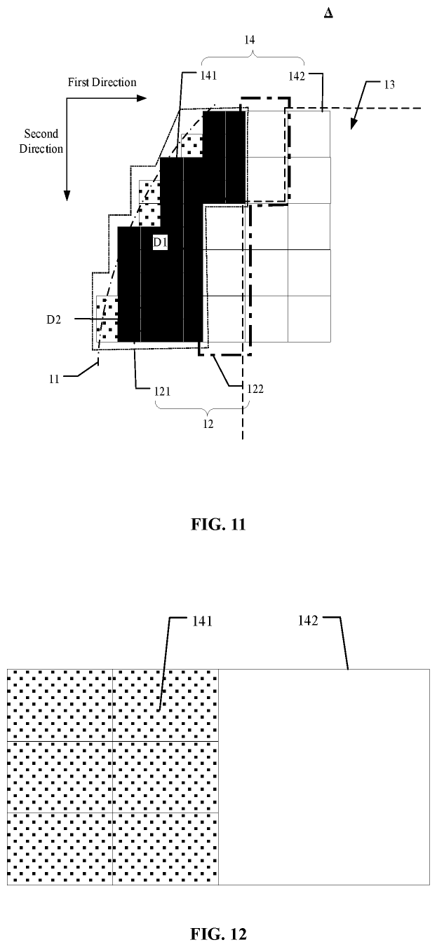

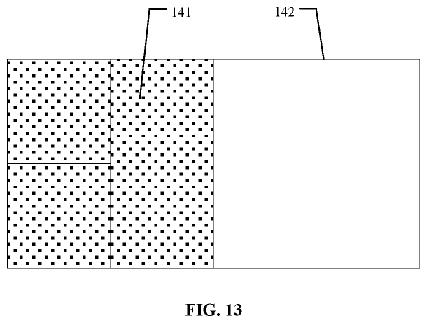

FIG. 12 is a schematic diagram of a first pixel unit and a second pixel unit according to an embodiment of the present disclosure, and FIG. 13 is another schematic diagram of the first pixel unit and the second pixel unit according to an embodiment of the present disclosure. In some embodiments, as shown in FIG. 12, the orthographic projection area of six adjacent first pixel units 141 on the light-emitting surface of the profiled display panel 100 may be equal to the orthographic projection area of one second pixel unit 142 on the light-emitting surface of the profiled display panel 100. Or, as shown in FIG. 13, the orthographic projection area of three adjacent first pixel units 141 on the light-emitting surface of the profiled display panel 100 may be equal to the orthographic projection area of one second pixel unit 142 on the light-emitting surface of the profiled display panel 100. Similarly, the orthographic projection area of 5, 7, or 8 adjacently arranged first pixel units 141 on the light-emitting surface of the profiled display panel 100 may be set to equal to the orthographic projection area of one second pixel unit 142 on the light-emitting surface of the profiled display panel 100. In addition, the present disclosure does not limit the arrangement of the first pixel units 141 included in the orthographic projection area of the orthographic projection area of one second pixel unit 142 on the light-emitting surface of the profiled display panel 100, and the user may adjustment the arrangement of the first pixel units 141 based on actual needs. Further, the present disclosure does not limit the size of the light transmission area 16 of each first pixel unit 141, and the user may adjust the size of the light transmission area 16 based on actual needs.

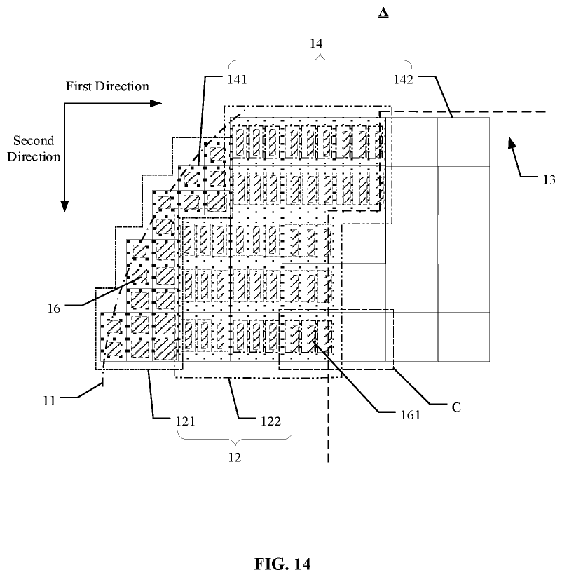

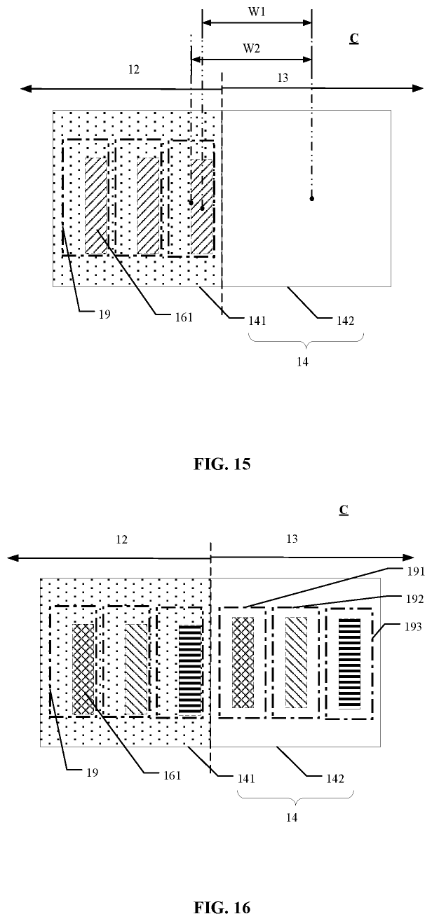

FIG. 14 is another schematic diagram of the area A in FIG. 1 according to an embodiment of the present disclosure, and FIG. 15 is a schematic diagram of an area C in FIG. 14 according to an embodiment of the present disclosure. Referring to FIG. 1, FIG. 14, and FIG. 15. In some embodiments, the first pixel unit 141 may include at least one sub-pixel 19. A minimum distance between the center point of the light transmission area 161 of the sub-pixel 19 and the regular display area 13 may be smaller than a minimum distance between the center point of its orthographic projection on the light-emitting surface of the profiled display panel 100 and the regular display area 13.

In some embodiments, each first pixel unit 141 located in the profiled display area 12 may include at least one sub-pixel 19, and a minimum distance W1 between the center point of the light transmission area 161 of at least some sub-pixels 19 and the regular display area 13 may be selected to be smaller than a minimum distance W2 between the center point of its orthographic projection on the light-emitting surface of the profiled display panel 100 and the regular display area 13. That is, as shown in FIG. 15, at least part of the specific light transmission area 161 of the sub-pixel 19 in the first pixel unit 141 is biased to the side of the regular display area 13 in the sub-pixel 19. Compared with the normally arranged sub-pixel 19, the light transmission area 161 in the normally arranged sub-pixel 19 is located in the middle of the sub-pixel 19. That is, in the embodiments of the present disclosure, the light transmission area (e.g., the light transmission area 161) of the sub-pixel 19 can be moved to the side of the regular display area 13 in the corresponding sub-pixel 19. In this way, the overall light transmission area (e.g., the light transmission area 161) of the corresponding first pixel unit 141 can be moved to the side of the regular display area 13, such that the display of a large number of first pixel units 141 in the profiled display area 12 can be tightly fused with the display of the regular display area 13, thereby weakening the display difference between the regular display area 13 and the profiled display area 12, and improving the display effect of the profiled display panel 100.

It should be noted that the “minimum distance” described above may refer to the shortest distance between the center point of the light transmission area 161 of the sub-pixel 19 and the edge of the regular display area 13 near the profiled display area 12.

FIG. 16 is another schematic diagram of the area C in FIG. 14 according to an embodiment of the present disclosure. Referring to FIG. 1, FIG. 14, and FIG. 16. In some embodiments, the pixel unit 14 may include M color sub-pixels 19, and M 2; the ratio of the light transmission area 161 of any color sub-pixel 19 in the profiled display area 12 to the sum of the areas of all first pixel units 141 may be equal to the ratio of the light transmission area 161 of the sub-pixel 19 of the same color in the regular display area 13 to the sum of the areas of all second pixel units 142.

In some embodiments, the pixel unit 14 of the profiled display panel 100 may include sub-pixels 19 of two or more colors. As shown in FIG. 14 and FIG. 16, one pixel unit 14 can include 3 sub-pixels 19. In some embodiments, the ratio of the light transmission area 161 of any color sub-pixel 19 in the profiled display area 12 to the area of all first pixel units 141 may be set to equal to the ratio of the light transmission area 161 of the same color sub-pixel 19 in the regular display area 13 to the area of all second pixel units 142. For example, when the pixel unit 14 of the profiled display panel 100 includes sub-pixels 19 of three colors, namely the red sub-pixel 191, the green sub-pixel 192, and the blue sub-pixel 193, the ratio of the red sub-pixel 191 in all the first pixel units 141 in the profiled display area 12 may be set to equal to the ratio of the red sub-pixel 191 in all the second pixel units 142 in the regular display area 13. Further, the ratio of the green sub-pixel 192 in all the first pixel units 141 in the profiled display area 12 may be set to equal to the ratio of the green sub-pixel 192 in all the second pixel units 142 in the regular display area 13, and the ratio of the blue sub-pixel 193 in all the first pixel units 141 in the profiled display area 12 may be set to equal to the ratio of the blue sub-pixel 193 in all the second pixel units 142 in the regular display area 13. In this way, the color display effect of the profiled display area 12 and the regular display area 13 can be consistent, especially when the entire profiled display panel 100 displays the same color, thereby avoiding the situation that there are differences in color display, and improving the display uniformity of the profiled display panel 100.

It should be noted that the equal ratios described above may be that the fluctuation of the ratios is within 10%, and ratios do not need to be identical.

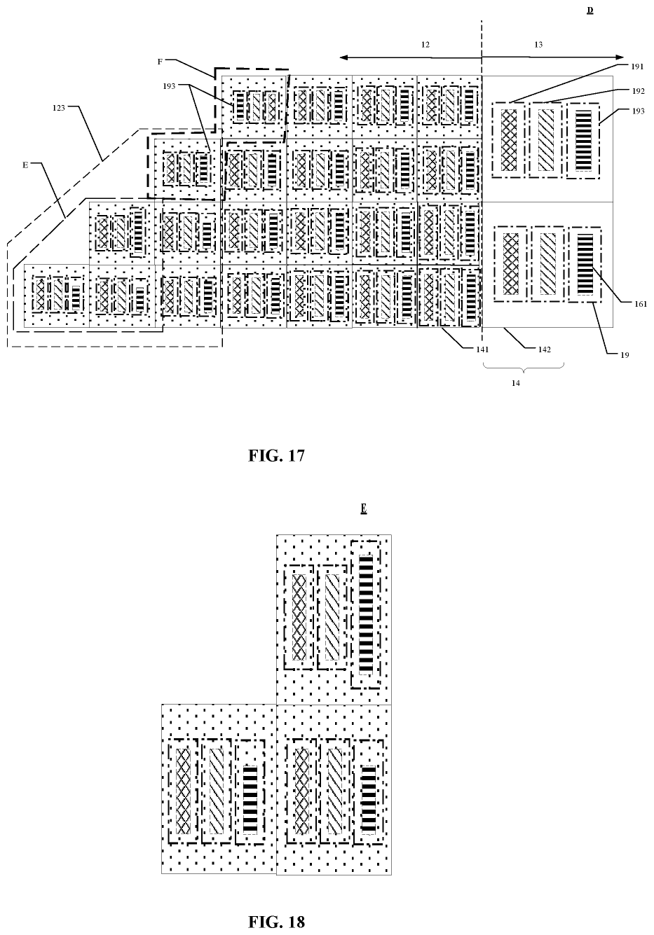

FIG. 17 is a schematic diagram of an area D in FIG. 9 according to an embodiment of the present disclosure, and FIG. 18 is an enlarged view of an area E in FIG. 17 according to an embodiment of the present disclosure. Referring to FIG. 1, FIG. 9, and FIG. 17. In some embodiments, along the extension direction of the profiled edge 11, the profiled display area 12 may include a third area 123, and the third area 123 may include a plurality of first pixel units 141. The ratio of the light transmission area 161 of at least one color sub-pixel 19 in the third area 123 to the sum of the areas of all corresponding first pixel units 141 may not equal to the ratio of the sum of the light transmission areas 161 of sub-pixels 19 of the same color in the regular display area 13 to the sum of the areas of all second pixel units 142. Along the extension direction of the profiled edge 11, the profiled display area 12 may include N adjacently arranged first pixel units 141, and the ratio of the light transmission area 161 of any color sub-pixel 19 to the sum of the areas of the corresponding first pixel units 141 may be equal to the ratio of the light transmission area 161 of the sub-pixels 19 of the same color in the regular display area 13 to the sum of the areas of all second pixel units 142, where N and N is an integer.

Along the extension direction of the profiled edge 11, there may be at least one area (e.g., the third area 123) in the profiled display area 12. The third area 123 may include several first pixel units 141. The ratio of the light transmission area 161 of a certain color sub-pixel 19 included in this part of the first pixel unit 141 to the area of this part of the first pixel unit 141 may be different from the ratio of the light transmission area 161 of the same color sub-pixel 19 in the regular display area 13 to the area of all second pixel units 142. Based on this, in some embodiments, along the extension direction of the profiled edge 11, the third area 123 may include a plurality of adjacently arranged first pixel units 141, and the ratio of the light transmission area 161 of any color sub-pixel 19 to the sum of areas of the corresponding first pixel units 141 may be set to equal to the ratio of the light transmission area 161 of the same color sub-pixel 19 in the regular display area 13 to the sum of the areas of all second pixel units 142.

As shown in FIG. 17, the third area 123 includes six first pixel units 141, and each first pixel unit 141 includes three sub-pixels 19, namely the red sub-pixel 191, the green sub-pixel 192, and the blue sub-pixel 193. In some embodiments, the ratio of the sum of the light transmission areas 161 of the blue sub-pixels 193 in the third area 123 to the sum of the light transmission areas 16 of the six first pixel units 141 may be less than the ratio of the sum of the light transmission areas 161 of the blue sub-pixels 193 in the regular display area 13 to the sum of the light transmission areas 16 of all second pixel units 142. However, in other embodiments, at least along the extension direction of the profiled edge 11 and in two adjacently arranged first pixel units 141 in the area E, the ratio of the sum of the light transmission areas 161 of the blue sub-pixels 193 to the sum of the light transmission areas 16 of the two first pixel units 141 may be equal to the ratio of the sum of the light transmission areas 161 of the blue sub-pixels 193 in the regular display area 13 to the sum of the light transmission areas 16 of all second pixel units 142.

That is, even if the ratio of the sub-pixels 19 of a certain color in an area is different from the ratio of the regular display area 13, as long as it can be ensured that the ratio of any color sub-pixel 19 in the plurality of sub-pixels 19 arranged next to the profiled edge 11 in the profiled display area 12 is the same as the ratio of the regular display area 13, it can be ensured that the display effect near the profiled edge 11 in the profiled display area 12 is the same as the display effect of the regular display area 13 as much as possible, thereby avoiding the situation that the display effect of the area near the profiled edge 11 is significantly different from the display effect of the regular display area 13 when the profiled display panel 100 is in the display state to avoid edge color separation, thereby avoiding the obvious jagged edge of the 100, and improving the display effect of the display panel.

Based on this, in each row of pixel units 14, the pixel units 14 arranged along the profiled edge 11 may include two or more than two color sub-pixels 19. The orthographic projection area of each color sub-pixel 19 included in the same pixel unit 14 on the light-emitting surface of the profiled display panel 100 may have different sizes. In addition, the light transmission area of the adjacently arranged sub-pixels 19 of each color on the light-emitting surface of the profiled display panel 100 may be adjusted, such that the light transmission area of each color sub-pixel 19 arranged along the profiled edge 11 on the light-emitting surface of the profiled display panel 100 may be nearly the same. In some embodiments, the ratio of the light transmission area of each color sub-pixel 19 to the light transmission area of all corresponding first pixel units 141 may be equal to the ratio of the light transmission area of the same color sub-pixel 19 in the regular display area 13 to the light transmission area of the second pixel units 142 to ensure that the display effect along the profiled edge 11 in the profiled display area 12 is the same as the display effect of the regular display area 13, thereby avoiding edge color separation, and improving the display effect of the display panel.

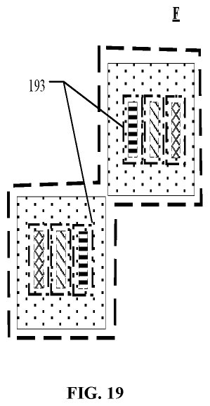

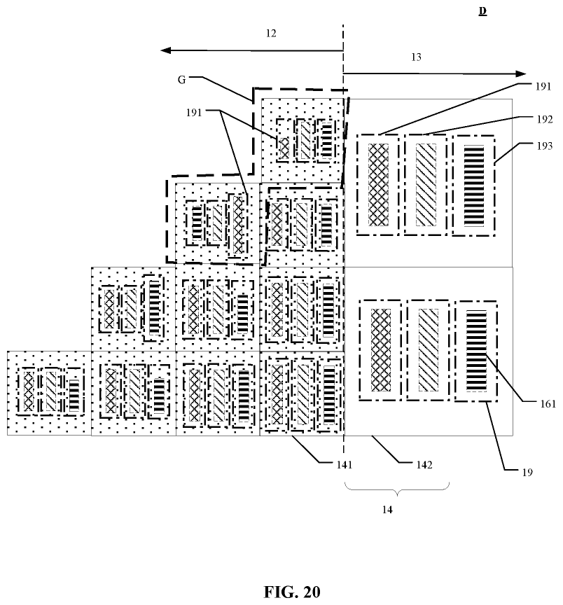

FIG. 19 is an enlarged view of an area F in FIG. 17 according to an embodiment of the present disclosure, and FIG. 20 is another schematic diagram of the area D in FIG. 9 according to an embodiment of the present disclosure. It should be noted that in order to clearly show the area G in FIG. 20, compared with FIG. 9, the number of pixel units 14 in the profiled display area 12 in reduced. The arrangement of the pixel units 14 in the profiled display area 12 shown in the accompanying drawings of the present disclosure is only for exemplary embodiment of the present disclosure, which is not used to limit the number of rows and columns in the pixel unit 14 in the profiled display area 12, and the user may adjust the number of rows, columns, size, shape, etc. of the pixel unit 14 in the profiled display area 12 based on needs. Referring to FIG. 1, FIG. 9, FIG. 17, FIG. 19, and FIG. 20. In some embodiments, along the extension direction of the profiled edge 11, there may be at least two adjacently arranged first pixel units 141, the sub-pixel 19 of any color in one first pixel unit 141 may be arranged close to the profiled edge 11, and the sane color sub-pixel 19 in the other first pixel unit 141 may be arranged away from the profiled edge 11.

In some embodiments, along the extension direction of the profiled edge 11, in at least two adjacently arranged first pixel units 141, there may be a certain sub-pixel 19 of the same color that is adjacently arranged in these two first pixel units 141. For example, as shown in FIG. 17, when the two first pixel units 141 each include three color sub-pixels, namely, the red sub-pixel 191, the green sub-pixel 192, and the blue sub-pixel 193, as shown in FIG. 17 and FIG. 19, the blue sub-pixel 193 in one of the first pixel units 141 may be arranged closer to the side of the profiled edge 11 than the other color sub-pixels 19 therein, and the blue sub-pixel 193 in the other first pixel unit 141 may be arranged farther away from the side of the profiled edge 11 than the other color sub-pixels 19 therein. In this way, the blue sub-pixels 193 in the two adjacently arranged first pixel units 141 can be adjacently arranged. That is, the present disclosure does not limit the arrangement order of the sub-pixels 19 of different colors included in the first pixel unit 141, and the user may adjust the arrangement order of the sub-pixels 19 based on actual needs.

Further, this arrangement utilizes the changing trend of the profiled edge 11. On one hand, in order to make the profiled edge 11 more delicate, the sub-pixels 19 may be set with different light transmission areas 16. For example, in order to adapt to the changing trend of the profiled edge 11, such as the area G shown in FIG. 20, the light transmission area 16 of the red sub-pixel 191 close to the profiled edge 11 may be selected to be reduced in proportion. However, in order to ensure that the overall chromaticity is normal, it is necessary to have the ratio of the light transmission area 16 of the three-color sub-pixels of the red sub-pixel 191, the green sub-pixel 192, and the blue sub-pixel 193 to be equal to the ratio of the regular display area 13. Then, the red sub-pixel 191 with a relatively large ratio of light transmission area 16 may be set in the nearby pixel unit. In order to adapt to the changing trend of the profiled edge 11, the sub-pixels with a relatively large ratio of light transmission area 16 may need to be arranged far away from the side of the profiled edge 11. Therefore, there may be two adjacent areas close to the profiled edge 11. One area may be arranged in the order of RGB, in which the ratio of R is relatively small, and the other area may be arranged in the order of BGR, in which the ratio of R may be relatively large, thereby ensuring that the chromaticity of the profiled edge 11 is not deviated, and ensuring the delicate display effect of the corresponding area of the profiled edge 11. In some embodiments, R may refer to the red sub-pixel, B may refer to the blue sub-pixel, and G may refer to the green sub-pixel.

It should be noted that the “equal area” and “equal distance” described above refer to the fact that the fluctuations of area and distance is within 10%, and the areas and distances do not need to be identical.

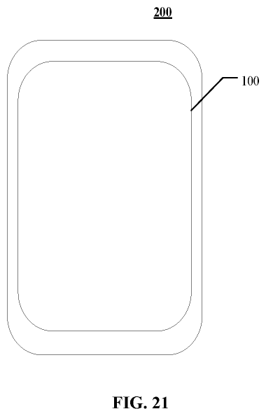

FIG. 21 is schematic diagram of a display device according to an embodiment of the present disclosure. Referring to FIG. 1, FIG. 3 to FIG. 18, and FIG. 21. Based on the same concept, an embodiment of the present disclosure further provides a display device 200. The display device 200 may include the profiled display panel 100, and the profiled display panel 100 may be any one of the profiled display panels 100 provided in the foregoing embodiments.

It should be understood that, for the embodiments of the display device 200 provided by the embodiments of the present disclosure, reference can be made to the descriptions of the profiled display panel 100 in the foregoing embodiments, which will not be repeated here. The display device 200 provided in the present disclosure may be any product and component with a display function, such as a mobile phone, a tablet, a television, a notebook computer, a navigator, etc.

Consistent with the present disclosure, the profiled display panel and the display device provided by the embodiments of the present disclosure at least achieve the following beneficial effects. In the profiled display panel and the display device provided by the embodiments of the present disclosure, by setting the orthographic projection area of the first pixel unit 141 located in the profiled display area to be smaller than or equal to the orthographic projection area of the second pixel unit located in the regular display area 13, and in the first direction and/or the second direction, by setting the distance between the center points of at least part of the adjacently arranged two first pixel units to be smaller than the distance between the center points of two adjacently arranged second pixel units, the pixel density of the edge pixel area (e.g., the profiled display area) can be increased, such that the jaggedness of pixels in the profiled edge area can be weakened, thereby making the edge display of the profiled display panel more smooth.

Although some specific embodiments of the present disclosure are described by examples in detail, those skilled in the art should understand that the above examples are only schematic and are not intended to limit the scope of the present disclosure. Those skilled in the art should understand that the above embodiments may be modified without deviating from the scope and spirit of the present disclosure. The scope of the disclosure is defined by the attached claims.

What is claimed is:

1. A profiled display panel comprising:
a profiled edge;
a regular display area;
a profiled display area, the profiled display area at least partially surrounding the regular display area, the profiled display area including the profiled edge; and
a plurality of pixel units, each pixel unit including a first pixel unit and a second pixel unit, the first pixel unit being located in the profiled display area, the second pixel unit being located in the regular display area, wherein:
an orthographic projection area of the first pixel unit on a light-emitting surface of the profiled display panel is S1, and an orthographic projection area of the second pixel unit on the light-emitting surface of the profiled display panel is S2, S1≤S2; and
along a first direction and/or a second direction, a distance between center points of at least part of two adjacently arranged first pixel units is R1, and along the first direction and/or the second direction, a distance between center points of tow adjacently arranged second pixel units is R2, R1<R2, the first direction intersecting the second direction.

2. The profiled display panel according to claim 1, wherein:
the profiled display area includes a first area, in the first area, S1<S2 and R1<R2.

3. The profiled display panel according to claim 2, wherein:
in the first area, along the first direction and/or the second direction, the orthographic projection areas of at least two adjacent first pixel units on the light-emitting surface of the profiled display panel are the same; and
along the first direction and/or the second direction, a light transmission area of the first pixel unit close to the profiled edge is smaller than the light transmission area of the first pixel unit away from the profiled edge.

4. The profiled display panel according to claim 2, wherein:
in the first area, along the first direction and/or the second direction, at least two adjacent first pixel units have different orthographic projection areas on the light-emitting surface of the profiled display panel.

5. The profiled display panel according to claim 4, wherein:
in the first area, the first pixel unit includes a first pixel unit A and a first pixel unit B, the orthographic projection area of the first pixel unit A on the light-emitting surface of the profiled display panel being S11, the orthographic projection area of the first pixel unit B on the light-emitting surface of the profiled display panel being S12, S11<S12;
along the first direction, the first pixel unit B is located on a side of the first pixel unit A facing the regular display area; and/or,
along the second direction, the first pixel unit B is located on the side of the first pixel unit A facing the regular display area.

6. The profiled display panel according to claim 2, wherein:
the profiled display area further includes a second area, the second area being located between the first area and the regular display area along a direction in which the profiled display area points to the regular display area, in the second area, S1=S2 and R1=R2.

7. The profiled display panel according to claim 6, wherein:
in the second area, the light transmission area of the first pixel unit is smaller than a light transmission area of the second pixel unit.

8. The profiled display panel according to claim 7, wherein:
in the second area, the orthographic projection areas of the first pixel units on the light-emitting surface of the profiled display panel are the same;
in the second area, the first pixel unit include a first pixel unit C and a first pixel unit D, the light transmission area of the first pixel unit C being P1, the light transmission area of the first pixel unit D being P2, P1<P2;
along the first direction, the first pixel unit D is located on a side of the first pixel unit C facing the regular display area; and/or,
along the second direction, the first pixel unit D is located on the side of the first pixel unit C facing the regular display area.

9. The profiled display panel according to claim 1, wherein:
in the profiled display area, the orthographic projection areas of the first pixel units on the light-emitting surface of the profiled display panel are the same, and the distance between the center points of two adjacently arranged first pixel units arranged along the first direction and/or the second direction is the same; and
along the first direction and/or the second direction, the light transmission area of the first pixel unit on the side close to the regular display area is larger than the light transmission area of the first pixel unit on the side away from the regular display area.

10. The profiled display panel according to claim 9, wherein:
along the first direction, at least two adjacently arranged first pixel units have the same light transmission area; and/or,
along the second direction, at least two adjacently arranged first pixel units have the same light transmission area.

11. The profiled display panel according to claim 2, wherein:
in the first area, along the first direction, the distance between the center points of at least two adjacently arranged first pixel units is D1, along the second direction, the distance between the center points of at least two adjacently arranged first pixel units is D2, D1<D2.

12. The profiled display panel according to claim 2, wherein:
in the first area, along the first direction, the distance between the center points of at least two adjacently arranged first pixel units is D1, along the second direction, the distance between the center points of at least two adjacently arranged first pixel units is D2, D2<D1.

13. The profiled display panel according to claim 1, wherein:
the first pixel unit includes at least one sub-pixel, a minimum distance between a center point of the light transmission area of the sub-pixel and the regular display area is smaller than a minimum distance between the center point of its orthographic projection on the light-emitting surface of the profiled display panel and the regular display area.

14. The profiled display panel according to claim 1, wherein:
the pixel unit include M color sub-pixels, M≥2; and
a ratio of a sum of the light transmission areas of any one of the color sub-pixels in the profiled display area to a sum of the areas of the first pixel units is equal to a ratio of a sum of the light transmission areas of the sub-pixels of the same color in the regular display area to a sum of areas of the second pixel units.

15. The profiled display panel according to claim 14, wherein:
along an extension direction of the profiled edge, the profiled display area includes a third area, the third area including a plurality of first pixel units, the ratio of the sum of the light transmission areas of at least one color sub-pixel in the third area to the sum of the corresponding areas of all first pixel units not being equal to the ratio of the sum of the light transmission areas of the sub-pixels of the same color in the regular display area to the sum of areas of the second pixel units;
along the extension direction of the profiled edge, in N adjacently arranged first pixel units, the ratio of the sum of light transmission areas of any color sub-pixel to the sum of the corresponding areas of the first pixel units is equal to the ratio of the sum of the light transmission areas of the sub-pixels of the same color in the regular display area to the sum of the areas of the second pixel units; N≥2 and N being an integer.

16. The profiled display panel according to claim 14, wherein:
along the extension direction of the profiled edge, there are at least two adjacently arranged first pixel units, any one of the color sub-pixels in one of the first pixel units being arranged close to the profiled edge, the sub-pixels of the same color in another first pixel unit being arranged away from the profiled edge.

17. A display device comprising:
a profiled display panel, the profiled display panel including:
a profiled edge;
a regular display area;
a profiled display area, the profiled display area at least partially surrounding the regular display area, the profiled display area including the profiled edge; and
a plurality of pixel units, each pixel unit including a first pixel unit and a second pixel unit, the first pixel unit being located in the profiled display area, the second pixel unit being located in the regular display area, wherein:
an orthographic projection area of the first pixel unit on a light-emitting surface of the profiled display panel is S1, and an orthographic projection area of the second pixel unit on the light-emitting surface of the profiled display panel is S2, S1≤S2;
along a first direction and/or a second direction, a distance between center points of at least part of two adjacently arranged first pixel units is R1, and along the first direction and/or the second direction, a distance between center points of tow adjacently arranged second pixel units is R2, R1<R2, the first direction intersecting the second direction.
